(19) United States
(12) Patent Application Publication
(10) Pub. No.: US 2009/0101386 A1
(43) Pub. Date: Apr. 23, 2009

(54) Size unconstrained faceplate display for use with infrastructure device

(75) Inventor: Roland Schoettle, American Canyon, CA (US)

Correspondence Address: OPTIMAL TECHNOLOGIES, INC., TWO PROGRESS PLAZA, 100 EAST DAVIE STREET, 19TH FLOOR, RALIEGH, NC, 27601, US

(73) Assignee: Optimal Innovations Inc., Bridgetown (BB)

(21) Appl. No.: 11/875,712

(22) Filed: Oct. 19, 2007

(51) Int. Cl. H05K 5/03

(52) U.S. Cl. 174/66

(57) ABSTRACT

The present invention is directed to a system and method which allows a display to have a dimension significantly greater than the actual dimension of the matching utility box or traditional utility box device faceplate. Thus, by making the size of the faceplate independent from the size of the matching utility box or traditional utility box faceplate, larger displays are possible which allows for larger size lettering and pictures and also allows for increased electronics within the display itself. In one embodiment, faceplate displays having double, triple or even quad-gang size can be positioned over a single-gang utility box thereby increasing the space for electronics as well as increasing the amount of (or size of) displayable material.

### CROSS-REFERENCE TO RELATED APPLICATIONS

This application is related to U.S. patent application Ser. No. 11/683,298 filed Mar. 7, 2007 entitled “LIGHT SWITCH USED AS A COMMUNICATION DEVICE”; U.S. patent application Ser. No. 11/683,326 filed Mar. 7, 2007 entitled “ANTICIPATORY UTILITY CONTROL DEVICE”; U.S. patent application Ser. No. 11/683,335 filed Mar. 7, 2007 entitled “PLUG AND PLAY UTILITY CONTROL MODULES”; U.S. Provisional Patent Application No. 60/956,314 filed Aug. 16, 2007 entitled “UTILITY OUTLETS AS A SECURITY SYSTEM”; U.S. Provisional Patent Application No. 60/940,010 filed May 24, 2007 entitled “LIGHT SWITCH AS A WIRELESS HUB”; U.S. Provisional Patent Application No. 60/940,010 filed May 24, 2007 entitled “UTILITY OUTLETS AS REMOTE CONTROL REPEATERS”; U.S. Provisional Patent Application No. 60/956,306 filed Aug. 16, 2007 entitled “USING UTILITY OUTLETS TO DETERMINE AND REPORT MEDIA-BASED ACTIVITY”, and U.S. patent application Ser. No. ______ filed Oct. 19, 2007, Attorney Docket No. 66816-P036US-10715041 entitled “INFRASTRUCTURE DEVICE WITH REMOVABLE FACE PLATE FOR REMOTE OPERATION,” the disclosures of which are incorporated herein by reference.

### TECHNICAL FIELD

This disclosure relates to infrastructure devices and more particularly to faceplate displays for such devices that are not limited in size by the confines of the infrastructure device.

### BACKGROUND OF THE INVENTION

Infrastructure devices are those devices that are mounted to a premises in such as manner as to be permanent or at least not easily removed therefrom. One aspect of an infrastructure device is that it is connected, at least electrically, to wiring affixed to the premises structure. Another aspect of an infrastructure device is that it is connected via wired or wireless communications to devices that are themselves connected electrically to the premises electricity delivery infrastructure. A light switch is one form of an infrastructure device. An electrical outlet is another form of such a device. A TV, radio, security system, surveillance system, premise-based communication system, or game box is yet another form of such device. Other infrastructure devices can be, for example, a wide variety of sensors/systems such as are obvious (e.g., light switches, plugs, thermostats, inline power boxes, etc) but also non-obvious sensors/systems such as light sensors, temperature sensors, internet access systems, WAN system, LAN systems, RF systems, display systems, power sensors, power supply systems, schedulers, clocks, audio/video systems, intercom systems, telephone systems, HVAC systems, television, radio, cameras, proximity sensors, occupancy sensors, GPS, entertainment systems, safety monitoring systems, security systems, fire monitoring systems, surveillance systems, messaging systems, alert and alarm systems, medical monitoring systems, data monitoring systems, data control systems, access monitoring systems, access control systems, legacy remote control systems (e.g., TVs, radios, lighting), media reader systems, identification systems, humidity sensors, barometric pressure sensors, weight sensors, traffic pattern sensors, power quality sensors, operating costs, power factor sensors, meters, storage systems, distributed generation systems, UPS systems, battery monitoring systems, priority systems, inertia sensors, glass break sensors, flood sensors, vibration sensors, smoke sensors, carbon dioxide sensors, carbon monoxide sensors, ultrasound sensors, infra-red sensors, microwave sensors, radiation sensors, bacteria sensors, disease sensors, poison sensors, germ sensors, toxic material sensors, air quality sensors, laser sensors, load sensors, load control systems, etc.

A common trait of infrastructure devices is that they are mounted in boxes, usually called utility boxes, permanently (for all practical purposes) affixed to the premises. Utility boxes come in various sizes with the smallest size (single gang) having a front opening of roughly 2½ inches wide and 4 inches tall. Utility boxes typically grow larger in the width direction. Thus a two-gang utility box has the same height (4 inches) but a width of 5 inches, with a triple-gang box having a width of 7½ inches, etc.

Utility device covers, called faceplates, are sized to fit the width of the box. Thus faceplates come in single-gang, double-gang, triple-gang, etc. sizes. All of these sizes have a similar height but vary in width. In situations such as discussed in one or more of the above-identified patent applications where it is desired to have the cover of a utility device act as an information display, the size limitations of a single-gang and possibly even a double-gang box limits the size of the displayed information. This then reduces the amount of information that can be displayed and/or reduces the size of the letters or images on the display. As a result, the distance away from the display a person can be and still be able to read it properly is also reduced.

In addition to the display size limitations imposed on a faceplate, for example, by a single-gang box, there is also a limitation as to the amount of electronics that can be positioned within the faceplate. For complex faceplate displays that can handle a number of different functions, the need for electronic footprint space is critical.

### BRIEF SUMMARY OF THE INVENTION

The present invention is directed to a system and method which allows a display to have a dimension significantly greater than the actual dimension of the matching utility box or traditional utility box device faceplate. Thus, by making the size of the faceplate independent from the size of the matching utility box or traditional utility box faceplate, larger displays are possible which allows for larger size lettering and pictures and also allows for increased electronics within the display itself. In one embodiment, faceplate displays having double, triple or even quad-gang size can be positioned over a single-gang utility box thereby increasing the space for electronics as well as increasing the amount of (or size of) displayable material.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with fiber objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawing, in which:

FIG. 1 is a schematic drawing showing one embodiment of the expanded faceplate utilized in an infrastructure electrical system;

FIGS. 2 and 3 are embodiments of expanded faceplates for use with single, double, triple or quad utility boxes;

FIG. 4 is an embodiment of an expanded faceplate for use for a single or double utility box;

FIG. 5 shows a view of the back of a faceplate illustrating one embodiment of how electrical contact is made to the premises utility system;

FIG. 6 shows one embodiment of a system in which two faceplates can be mated side by side to form a double width faceplate; and

FIGS. 7A through 7D show different sizes and shapes of a faceplate utilized in an infrastructure electrical system.

### DETAILED DESCRIPTION OF THE INVENTION

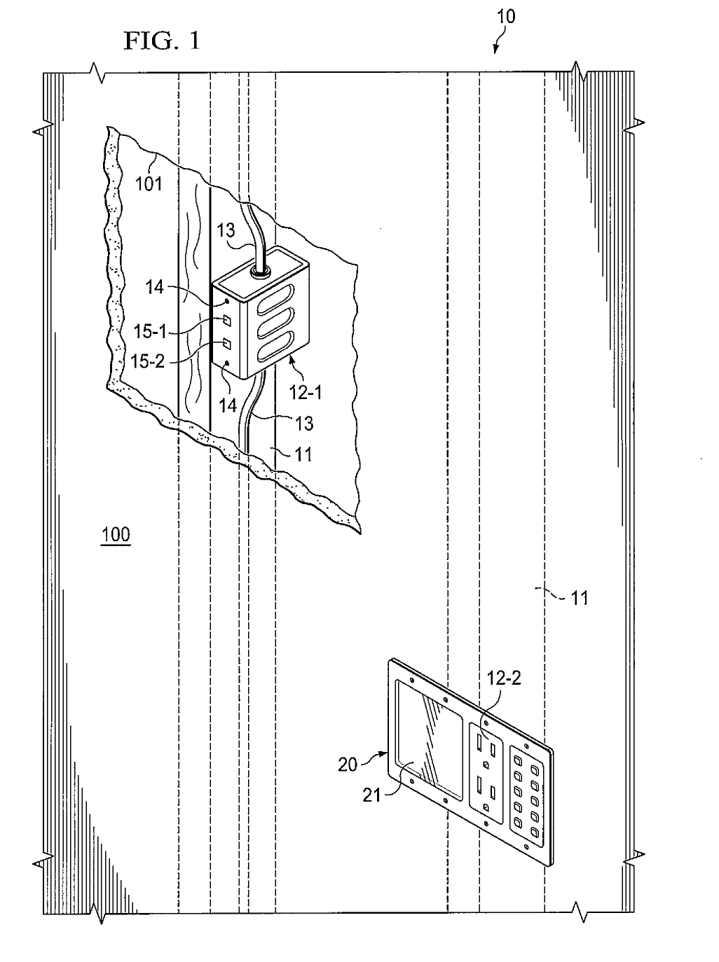

FIG. 1 is a schematic drawing showing one embodiment of the expanded faceplate, such as faceplate 20, employed in an infrastructure electrical system. System 10 as shown in FIG. 1 illustrates wall 100 that is part of the premises structure. Wall 100 is supported by studs 11 and has a cut-away portion 101 that shows utility box 12-1 fastened permanently to a stud 11. Electrical cables, such as cables 13 are connected to box 12-1 and are terminated within the box in any well-known manner. Box 12-1 has screw holes 14 positioned to accept a faceplate (not shown in conjunction with box 12-1). Utility box 12-1 can accept any number of utility switches, plugs, or other devices. Also, shown within box 12-1 are contacts 15-1 and 15-2 which are positioned to provide electrical communication with a faceplate, if necessary. Utility box 12-1 is positioned in a location where one would typically expect to find a light switch.

Also shown in FIG. 1 is a second utility box 12-2 positioned in a location where one would typically expect to see a power outlet (electrical socket). Box 12-2 has connected thereto faceplate 20 which in this embodiment is a four-gang sized faceplate covering single-gang utility box 12-2.

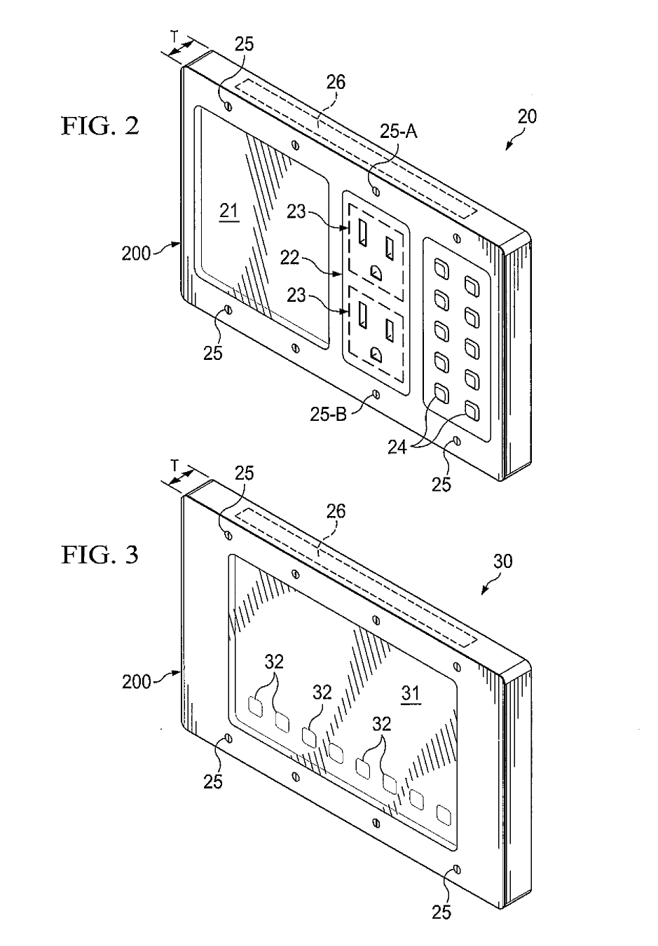

FIG. 2 shows one embodiment 20 of expanded faceplate 200 for use with single, double, triple, quad, etc. utility boxes. Holes 25 are used to fasten the faceplate to the desired utility box by using traditional screws. Of course, any other method of fastening the faceplate to the box can be employed, including, for example, snap or spring loaded connectors, magnets, etc. In the embodiment shown, one portion of the faceplate has an opening 22 to cover a traditional electrical socket 23, or the socket can be part of the faceplate. When the socket is part of the faceplate, portions of the socket could extend into the utility box, such as into utility box 12-2, FIG. 1. If the socket is extended into the box, then screw holes 25A and 25B are used in conjunction with holes 14 in the mating box to position the faceplate. The faceplate then extends to the right of the utility box by one gang width and extends to the left of the utility box by two gang widths, as shown in FIG. 1. Faceplate 200 has display 21, keypad 24, as well as internal electronics 26, and can have any thickness T desired.

Note that the exact width or height of the faceplate is not critical but should for esthetic reasons fit into the decor of the premise to which it is to be used. Thus, the size (both height and width) should be such as to be pleasing to the eye and not make the faceplate appear as though it is foreign to the environment. In most cases, this would dictate that the faceplate width be made to appear to be a multiple (such as two, three, four, five, six, etc) of a standard single-gang faceplate. Thus, while the faceplate need not be exactly a gang box width multiple, it should be close enough to such a multiple so as to not appear to be out of place. Note also that the faceplate display could, subject to any element positioned on the faceplate that would need to fit into a utility box, extend left or right (or up/down) of the box by any amount. Also note that traditional faceplates are marginally larger than the utility box. In the discussion herein, the faceplate is significantly larger. In this context, ‘significantly’ means that to the user's eye, it appears to be wider (taller) than a typical gang box by at least one inch and in most cases, by at least two inches.

Note that using the concepts of the invention, commonly available LCD panels normally destined for small notebook computers or portable DVD players and that have a traditional 3×4 or 6×9 aspect ratio, can be used as a faceplate of desired, even though such devices do not fit the standard light switch cover height parameters.

The front surface of the faceplate would have a display or other user-visible operational elements distributed across substantially all of the front surface, regardless of the faceplate size. The term ‘substantially all’ does not imply that every portion of the faceplate must have some visible display but rather that there are no large gaps or obviously missing elements as there would be, for example, if one where to place a traditional two-gang faceplate over a single-gang utility box. In such a situation, the area of the faceplate in front of the ‘missing’ gang-box would be blank, or substantially blank, because there could be no display device mounted in the ‘missing’ box. In some cases the ‘substantially all’ test would be satisfied if the faceplate contained a gap for a device mounted in a gang-box. For example, assume a triple-gang width faceplate display were to be used with a switch mounted in a single-gang utility box. The triple-gang faceplate could have an opening therein (either in a center position, or left or right of center) to accept a utility box mounted switch.

Note that in most applications, the triple-gang faceplate would likely be one piece that can be attached on via connectors on the faceplate back-side to the actual ‘in-box” switching module using a two piece design (the faceplate and the switching module). A preferred approach then would be to allow the switching module to be connected to the faceplate in a “centered”, “left”, and “right” side orientation. In other words, the faceplate could be centered on the box or offset to the left or right side of the box (or up or down) according to how the faceplate might best look on the wall so as to provide better placement than where the box is actually located. In such a situation, the backside of the faceplate would have a sophisticated connection system (not shown) to cover reasonable switch and faceplate mounting combinations.

FIG. 3 shows one embodiment 30 of faceplate 200 having display 31 with soft keys 32. This display and keys can be programmed under the control of an internal or external processor.

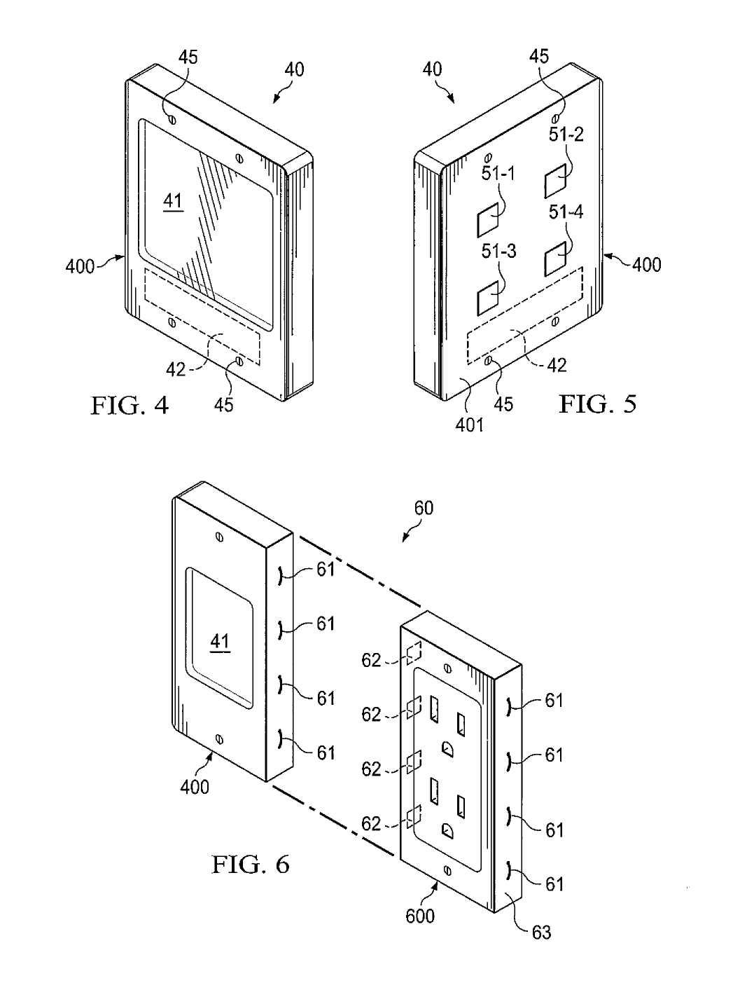

FIG. 4 shows one embodiment 40 of an expanded faceplate, such as faceplate 400, for use with a single or double utility box. Faceplate 400 also has display 41 for allowing a user to use the utility system to perform a wide variety of functions. Holes 45 are used, as discussed above, to mount the faceplate to the utility box or to a device already mounted in the utility box. Electronic circuitry 42 can be, if desired, contained within faceplate 400.

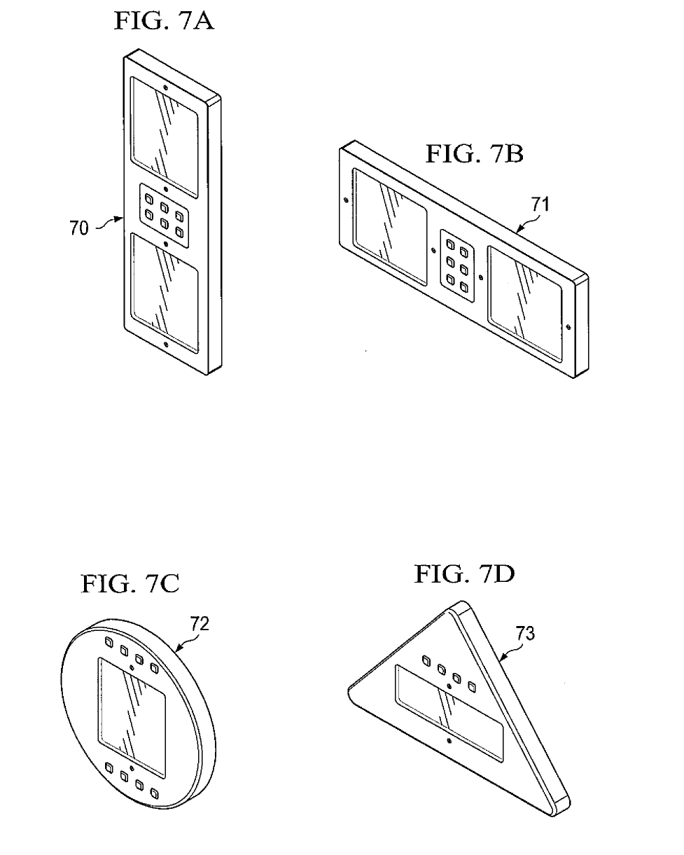

FIGS. 7A through 7D shown that the faceplate can be any size or shape desired to work with any size utility box and to fit the décor or the physical limitations of the premises. Thus, a “tall” (higher than it is wide) faceplate (70, FIG. 7A) can be used where horizontal space is not practical. A wide faceplate (71, FIG. 7B) can be used when vertical size is not desired. FIG. 7C shows a round faceplate 72 and FIG. 7D shows a triangular faceplate 73. Any geometry and/or size can utilize the concepts discussed herein.

FIG. 5 shows a view of back surface 401 of a faceplate illustrating one embodiment of how electrical contact is made to the premises utility system. In his embodiment, contacts 51-1 to 51-4 are used for mating with contacts, such as contacts 15-1, 15-2 (FIG. 1) located in the mated utility box. Communication between the faceplate and the utility box (or devices within the utility box) can be by electrical contact, as shown or wirelessly by RF, optics or any other method. Wireless connection would facilitate offset faceplate mounting as discussed above.

FIG. 6 shows system 60 in which two faceplates are mated side by side to form a double width faceplate. Note that while each of these faceplates is shown as a single-gang width faceplate, they can be any width or height desired and any number of widths (or heights) can be added as desired. Multiple faceplates can thus be combined to form a unified faceplate having an expanded width to allow for necessary electronics and display size that fits the intended usage. The faceplates can be, for example, connected together using male/female clips 61, 62, as shown, or by using any other connecting mechanism. A cover (not shown) can be used to cover the open ends, such as open end 63, to hide the unused clips.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A faceplate for use in conjunction with an infrastructure utility box, said faceplate comprising:
a front surface area having a width with yields the appearance of which is at least a multiple of X times the width of a single-gang faceplate,
said front surface having thereon user-visible operational elements across substantially all of said surface area; and
means for mounting said faceplate to a utility box having a gang-number at least one gang less than X.

2. The faceplate of claim 1 wherein at least one of said operational elements is a display.

3. The faceplate of claim 2 wherein at least one of said operational elements is a device which extends into a gang-box.

4. The faceplate of claim 2 further comprising said faceplate to be offset from a device which extends into a utility box.

5. The faceplate of claim 1 further comprising:
electronic circuitry contained within said faceplate.

6. The faceplate of claim 5 wherein said electronic circuitry comprises at least one display for providing informational content to a user.

7. The faceplate of claim 1 further comprising:
means for exchanging communications between said faceplate and said utility box.

8. The faceplate of claim 7 wherein said exchanging means comprises contacts positioned on a back surface of said faceplate.

9. A method of increasing the displayable area of a utility device faceplate, said method comprising:
fastening a faceplate containing a displaying area of gang-width Y to a utility box having a gang width X, where X is significantly less than Y.

10. The method of claim 9 where Y is at least 1½ times X.

11. The method of claim 9 wherein said utility box has an area of A and said display has an area visibly greater than A.

12. The method of claim 9 further comprising:
selecting faceplate with a display area having a physical shape to fit a particular location.

13. The method of claim 9 wherein said fastening comprises:
positioning at least a portion of said faceplate over a device mounted in said utility box.

14. A display for use in conjunction with premises utility systems, said display comprising:
a user-visible area defined by a height yielding an appearance of a traditional faceplate used in said premises;
said user-visible area farther defined by a width having an appearance of a traditional faceplate of at least (X gang-widths where X is the number of gang-widths of an existing utility box to which said display is to be at least temporarily attached.

15. The display of claim 14 wherein said height is approximately 4 inches and wherein each gang width is approximately 2½ inches.

16. The display of claim 14 further comprising:
connection points for allowing said display to become attached to said utility box in any of a number of orientations with respect to center, left, right of a centerline of said box.

17. The display of claim 15 further comprising:
at least one device mounted on said display having a depth sufficient for extending into said utility box.

18. The display of claim 15 further comprising:
an opening for accommodating a device mounted in said utility box.

19. The display of claim 14 further comprising:
means for exchanging communications between said display and said utility box.

20. The display of claim 19 wherein said exchanging means comprises contacts positioned on a back surface of said display.

21. A display for use in conjunction with a premises utility system, said display comprising:
a user-visible area having an appearance selected by a user to conform to requirements imposed by said user; and
means for allowing said display to become attached to an existing infra-structure utility box.

22. The display of claim 21 further comprising:
connection points for allowing said display to become attached to said utility box in any of a number of orientations with respect to center, left, right, up, down of a centerline of said utility box.
